(19) United States
(12) Patent Application Publication
(10) Pub. No.: US 2024/0030332 A1
(43) Pub. Date: Jan. 25, 2024

(54) SEMICONDUCTOR DEVICE, SEMICONDUCTOR MODULE, AND WIRELESS COMMUNICATION APPARATUS

(71) Applicant: SONY GROUP CORPORATION, TOKYO (JP)

(72) Inventors: KUNIHIKO TASAI, TOKYO (JP); TAKAHIRO KOYAMA, TOKYO (JP); NORIYUKI FUTAGAWA, TOKYO (JP); SEI FUKUSHIMA, TOKYO (JP); YUYA KANITANI, TOKYO (JP)

(21) Appl. No.: 18/041,870

(22) PCT Filed: Aug. 5, 2021
(86) PCT No.: PCT/JP2021/029047

§ 371 Date: Feb. 16, 2023

(30) Foreign Application Priority Data
Sep. 1, 2020 (JP) 2020-147166

(51) Int. Cl. H01L 29/778; H01L 29/20; H01L 29/66

(52) U.S. Cl. CPC H01L 29/7786; H01L 29/2003; H01L 29/66462

(57) ABSTRACT

A semiconductor device including: a channel layer; a spacer layer; an intermediate layer; and a barrier layer. The channel layer includes a first nitride semiconductor. The spacer layer includes a second nitride semiconductor having a larger band gap than a band gap of the first nitride semiconductor. The spacer layer is provided on the channel layer. The intermediate layer includes Alₓ₁In_{y1}Ga_{(1-x1-y1)}N(0<x1<1, 0<y1<1, and 0<x1+y1<1). The intermediate layer is provided on the spacer layer. The barrier layer includes Alₓ₂In₍₁₋ₓ₂₎N(0<x2<1). The barrier layer is provided on the intermediate layer.

### TECHNICAL FIELD

The present disclosure relates to a semiconductor device, a semiconductor module, and a wireless communication apparatus.

### BACKGROUND ART

In recent years, high electron mobility transistors (High Electron Mobility Transistors: HEMTs) have been actively studied and developed in which nitride semiconductors are used. Nitride semiconductors each have a larger band gap than the band gaps of Si, GaAs, and the like and each have polarization specific to the hexagonal crystal family. HEMTs in which nitride semiconductors are used are thus promising as low-resistance and high-withstand-voltage transistors that are each able to perform a high-speed operation.

Specifically, HEMTs are expected to be applied to power devices, RF(Radio Frequency) devices, or the like. For example, HEMTs in which AlGaN is used for barrier layers have been put into practical use for base stations or the like for satellite communication or wireless communication.

Further, HEMT in which AlInN is used for a barrier layer has been proposed in recent years (e.g., PTL 1). The HEMT in which AlInN is used for a barrier layer is able to achieve still higher two-dimensional electron gas concentration than that of HEMT in which AlGaN is used for a barrier layer. The HEMT in which AlInN is used for a barrier layer is thus expected to allow for still higher power.

### CITATION LIST

### Patent Literature

PTL 1: Japanese Unexamined Patent Application Publication No. 2018-56299

### SUMMARY OF THE INVENTION

Here, AlInN is lower in crystal growth temperature than other nitride semiconductors including AlGaN, GaN, and the like. Therefore, for example, in a case where an n-type semiconductor layer is regrown or ion implantation is performed to reduce the resistance between a source or drain electrode and a channel, a thermal history of these process steps may deteriorate the crystal structure of AlInN. As a result, the sheet resistance of a channel of HEMT may increase and the device characteristics may be decreased. The HEMT is thus requested to have higher heat resistance for a barrier layer including AlInN.

It is therefore desirable to provide a semiconductor device having higher heat resistance, a semiconductor module including the semiconductor device, and a wireless communication apparatus including the semiconductor device.

A semiconductor device according to an embodiment of the present disclosure includes: a channel layer; a spacer layer; an intermediate layer; and a barrier layer. The channel layer includes a first nitride semiconductor. The spacer layer includes a second nitride semiconductor having a larger band gap than a band gap of the first nitride semiconductor. The spacer layer is provided on the channel layer. The intermediate layer includes Alₓ₁In_{y1}Ga_{(1-x1-y1)}N(0<x1<1, 0<y1<1, and 0<x1+y1<1). The intermediate layer is provided on the spacer layer. The barrier layer includes Alₓ₂In₍₁₋ₓ₂₎N(0<x2<1). The barrier layer is provided on the intermediate layer.

A semiconductor module according to an embodiment of the present disclosure includes a semiconductor device. The semiconductor device includes a channel layer, a spacer layer, an intermediate layer, and a barrier layer. The channel layer includes a first nitride semiconductor. The spacer layer includes a second nitride semiconductor having a larger band gap than a band gap of the first nitride semiconductor. The spacer layer is provided on the channel layer. The intermediate layer includes Alₓ₁In_{y1}Ga_{(1-x1-y1)}N(0<x1<1, 0<y1<1, and 0<x1+y1<1). The intermediate layer is provided on the spacer layer. The barrier layer includes Alₓ₂In₍₁₋ₓ₂₎N(0<x2<1). The barrier layer is provided on the intermediate layer.

A wireless communication apparatus according to an embodiment of the present disclosure includes a semiconductor device. The semiconductor device includes a channel layer, a spacer layer, an intermediate layer, and a barrier layer. The channel layer includes a first nitride semiconductor. The spacer layer includes a second nitride semiconductor having a larger band gap than a band gap of the first nitride semiconductor. The spacer layer is provided on the channel layer. The intermediate layer includes Alₓ₁In_{y1}Ga_{(1-x1-y1)}N(0<x1<1, 0<y1<1, and 0<x1+y1<1). The intermediate layer is provided on the spacer layer. The barrier layer includes Alₓ₂In₍₁₋ₓ₂₎N(0<x2<1). The barrier layer is provided on the intermediate layer.

In the semiconductor device, the semiconductor module, and the wireless communication apparatus according to the respective embodiments of the present disclosure, the channel layer, the spacer layer, the intermediate layer, and the barrier are sequentially stacked. The channel layer includes the first nitride semiconductor. The spacer layer includes the second nitride semiconductor having a larger band gap than that of the first nitride semiconductor. The intermediate layer includes AlInGaN. The barrier includes AlInN. This makes it possible, for example, in the semiconductor device to suppress the diffusion of alloy between the channel layer and the barrier layer by heat treatment.

### BRIEF DESCRIPTION OF DRAWING

FIG. 1 is a vertical cross-sectional view of a configuration of a semiconductor device according to an embodiment of the present disclosure.

FIG. 2 is a graphical chart illustrating a band lineup of conduction band minimums of a stacked body in which a channel layer, a spacer layer, and a barrier layer are stacked.

FIG. 3 is a graphical chart illustrating a band lineup of conduction band minimums of a stacked body in which the channel layer, the spacer layer, an intermediate layer, and the barrier layer are stacked.

FIG. 4 is a vertical cross-sectional view of a step of a method of manufacturing the semiconductor device according to the embodiment.

FIG. 5 is a vertical cross-sectional view of a step of the method of manufacturing the semiconductor device according to the embodiment.

FIG. 6 is a vertical cross-sectional view of a step of the method of manufacturing the semiconductor device according to the embodiment.

FIG. 7 is a vertical cross-sectional view of a step of the method of manufacturing the semiconductor device according to the embodiment.

FIG. 8 is a vertical cross-sectional view of a step of the method of manufacturing the semiconductor device according to the embodiment.

FIG. 9 is a vertical cross-sectional view of a step of the method of manufacturing the semiconductor device according to the embodiment.

FIG. 10 is a vertical cross-sectional view of a configuration of a semiconductor device according to a first modification example.

FIG. 11 is a vertical cross-sectional view of a configuration of a semiconductor device according to a second modification example.

FIG. 12 is a vertical cross-sectional view of a configuration of a semiconductor device according to a third modification example.

FIG. 13 is a vertical cross-sectional view of a configuration of a semiconductor device according to a fourth modification example.

FIG. 14 is a schematic perspective view of a configuration of a semiconductor module.

FIG. 15 is a block diagram illustrating a configuration of a wireless communication apparatus.

FIG. 16 is a scatter diagram illustrating results of measurement of sheet resistance of two-dimensional electron gas layers generated in stacked bodies according to a working example and a comparative example.

### MODES FOR CARRYING OUT THE INVENTION

The following describes embodiments of the present disclosure in detail with reference to the drawings. The embodiments described below are specific examples of the present disclosure. The technology according to the present disclosure is not limited to the following modes. In addition, the disposition, dimensions, dimensional ratios, and the like of the respective components according to the present disclosure are not limited to the modes illustrated in the drawings.

It is to be noted that description is given in the following order.
1. Configuration of Semiconductor Device
2. Method of Manufacturing Semiconductor Device
3. Modification Examples
4. Application Examples
4.1. Semiconductor Module
4.2. Wireless Communication Apparatus

### 1. Configuration of Semiconductor Device

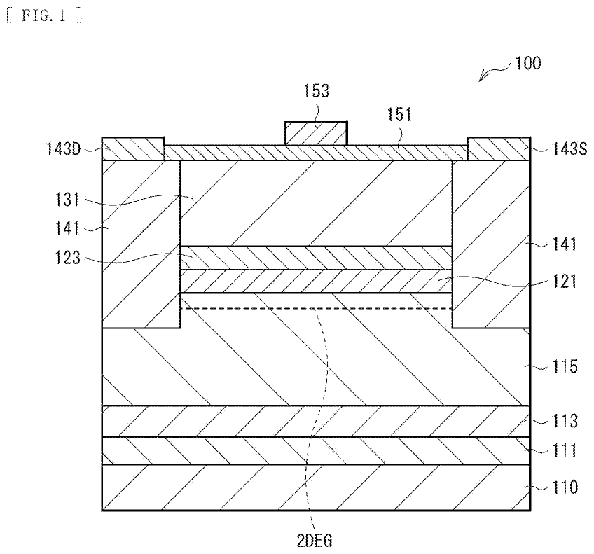

First, a configuration of a semiconductor device according to an embodiment of the present disclosure is described with reference to FIG. 1. FIG. 1 is a vertical cross-sectional view of a configuration of a semiconductor device 100 according to the present embodiment.

As illustrated in FIG. 1, the semiconductor device 100 includes a substrate 110, a first buffer layer 111, a second buffer layer 113, a channel layer 115, a spacer layer 121, an intermediate layer 123, a barrier layer 131, a regrowth layer 141, a source electrode 143S, a drain electrode 143D, a gate insulating film 151, and a gate electrode 153.

The semiconductor device 100 according to the present embodiment is a high electron mobility transistor (HEMT) that uses a two-dimensional electron gas layer (2DEG) as a channel. The two-dimensional electron gas layer (2DEG) is generated by using the difference between the magnitude of the polarization of the channel layer 115 and the magnitude of the polarization of the barrier layer 131. The two-dimensional electron gas layer (2DEG) is generated, for example, at the interface of the channel layer 115 on the barrier layer 131 side.

The substrate 110 is a supporting body of the semiconductor device 100. For example, the substrate 110 may be a SiC substrate, a sapphire substrate, a Si substrate, or the like. The semiconductor device 100 is provided with the first buffer layer 111 and the second buffer layer 113 that reduce the lattice constant mismatch between the substrate 110 and the channel layer 115. Therefore, the substrate 110 may be a substrate including a material having a different lattice constant from that of the channel layer 115.

However, the substrate 110 may be a substrate including a semiconductor material having a lattice constant close to that of the nitride semiconductor included in the channel layer 115. For example, the substrate 110 may be a substrate including a III-V group compound semiconductor such as GaN or AlN. In such a case, it is possible to form the channel layer 115 more easily in the semiconductor device 100. The channel layer 115 is obtained by epitaxially growing a nitride semiconductor.

The first buffer layer 111 and the second buffer layer 113 each include an epitaxially grown nitride semiconductor. The first buffer layer 111 and the second buffer layer 113 are provided on the substrate 110. Control over the lattice constant of the surface provided with the channel layer 115 allows the first buffer layer 111 and the second buffer layer 113 to reduce the lattice mismatch between the substrate 110 and the channel layer 115. This allows the first buffer layer 111 and the second buffer layer 113 to offer a more favorable crystal state for the channel layer 115 and suppress the warpage of the substrate 110.

For example, in a case where the substrate 110 is a single-crystal Si substrate having a (111) plane as the principal surface and the channel layer 115 is a GaN layer, the first buffer layer 111 may include AlN and the second buffer layer 113 may include AlGaN. However, depending on the configurations of the substrate 110 and the channel layer 115, the first buffer layer 111 and the second buffer layer 113 may be omitted or the first buffer layer 111 alone may be provided.

The channel layer 115 includes a nitride semiconductor having a smaller band gap than the band gaps of the spacer layer 121 and the barrier layer 131. The channel layer 115 is provided on the second buffer layer 113. The channel layer 115 allows carriers to be accumulated at the interface on the barrier layer 131 side by using the difference from the magnitude of the polarization of the barrier layer 131.

Specifically, the channel layer 115 may include epitaxially grown Alₓ₄In_{y4}Ga_{(1-x4-y4)}N (0<x4<1, 0<y4<1, and 0<x4+y4<1). For example, the channel layer 115 may include epitaxially grown GaN, InGaN, InN, AlGaN, or AlInGaN. More specifically, the channel layer 115 may include undoped u-GaN to which no impurity is added. In such a case, the channel layer 115 makes it possible to suppress the impurity scattering of the carriers. It is thus possible to increase the carrier mobility.

The spacer layer 121 includes a nitride semiconductor having a lager band gap than that of the channel layer 115. The spacer layer 121 is provided on the channel layer 115. The spacer layer 121 reduces alloy scattering between the barrier layer 131 and the channel layer 115 and makes it possible to suppress a decrease in the carrier mobility of the two-dimensional electron gas layer (2DEG) by the alloy scattering.

Specifically, the spacer layer 121 may include epitaxially grown Alₓ₃In_{y3}Ga_{(1-x3-y3)}N (0<x3<1, 0<y3<1, and 0<x3+y3<1). For example, the spacer layer 121 may include AlN. Alternatively, the spacer layer 121 may include AlGaN or AlInGaN.

In addition, it is preferable that the spacer layer 121 have, for example, a thickness of 0.5 nm or more and 3 nm or less. In a case where the spacer layer 121 has a thickness of 0.5 nm or more, it is possible to form the spacer layer 121 more easily. Meanwhile, in a case where the spacer layer 121 has a thickness of 3 nm or less, it is possible to appropriately control the profile of the band gap of the semiconductor device 100 as described below and the spacer layer 121 thus makes it possible to further increase the carrier density of the two-dimensional electron gas layer (2DEG) generated in the channel layer 115.

The intermediate layer 123 includes epitaxially grown Alₓ₁In_{y1}Ga_{(1-x1-y1)}N(0<x1<1, 0<y1<1, and 0<x1+y1<1). The intermediate layer 123 is provided on the spacer layer 121. Alₓ₁In_{y1}Ga_{(1-x1-y1)}N included in the intermediate layer 123 is a quaternary nitride semiconductor and it is thus easy to obtain a mixed crystal that is more excellent in single-crystallinity than Alₓ₂In₍₁₋ₓ₂₎N included in the barrier layer 131. The intermediate layer 123 further clarifies the interface between the barrier layer 131 and the spacer layer 121 and makes it possible suppress heat making the interface unclear. It is thus possible to suppress the deterioration of the layer structure of the channel layer 115 and the barrier layer 131 by heat.

It is preferable that Alₓ₁In_{y1}Ga_{(1-x1-y1)}N included in the intermediate layer 123 have a Ga composition (1-x1-y1) of 0.01 or more and 0.3 or less. In a case where the intermediate layer 123 has a Ga composition (1-x1-y1) of 0.01 or more and 0.3 or less, the intermediate layer 123 has further increased crystallinity and it is possible to suppress heat making the interface unclear. It is thus possible to suppress the deterioration of the layer structure of the channel layer 115 and the barrier layer 131 by heat.

In addition, it is preferable that the intermediate layer 123 have a thickness of 0.5 nm or more and 10 nm or less. In a case where the intermediate layer 123 has a thickness of 0.5 nm or more, it is possible to form the intermediate layer 123 more easily. Meanwhile, in a case where the intermediate layer 123 has a thickness of 10 nm or less, it is possible to appropriately control the profile of the band gap of the semiconductor device 100 as described below and the intermediate layer 123 thus makes it possible to further increase the carrier density of the two-dimensional electron gas layer (2DEG) generated in the channel layer 115. It is to be noted that it is more preferable that the intermediate layer 123 have a thickness of 1.0 nm or more and 5.0 nm or less.

The barrier layer 131 includes a nitride semiconductor having a lager band gap than that of the channel layer 115. The barrier layer 131 is provided on the intermediate layer 123. The barrier layer 131 allows carriers to be accumulated in the channel layer 115 on the barrier layer 131 side by spontaneous polarization or piezoelectric polarization. This makes it possible to form the two-dimensional electron gas layer (2DEG) having high mobility and high carrier concentration in the channel layer 115 on the barrier layer 131 side in the semiconductor device 100.

Specifically, the barrier layer 131 includes epitaxially grown Alₓ₂In₍₁₋ₓ₂₎N(where 0<x2<1). For example, the barrier layer 131 may include undoped u-Alₓ₂In₍₁₋ₓ₂₎N to which no impurity is added. In such a case, the barrier layer 131 makes it possible to suppress the impurity scattering of the carriers in the channel layer 115. It is possible to further increase the carrier mobility.

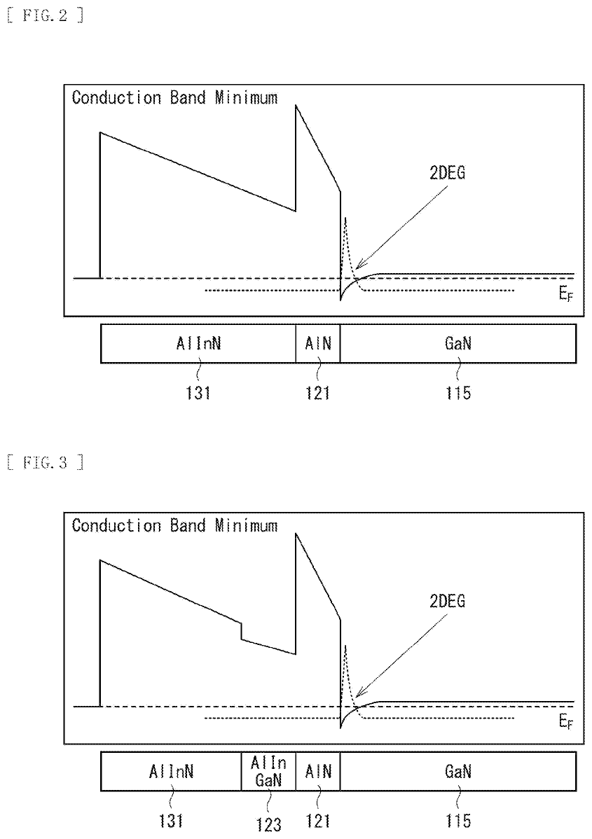

It is possible to control the carrier density of the two-dimensional electron gas layer (2DEG) by using, for example, the profile of the band gap of each of the layers from the barrier layer 131 to the channel layer 115. The control over the carrier density of the two-dimensional electron gas layer (2DEG) is described with reference to FIGS. 2 and 3. FIG. 2 is a graphical chart illustrating a band lineup of the conduction band minimums of a stacked body in which the channel layer 115, the spacer layer 121, and the barrier layer 131 are stacked. FIG. 3 is a graphical chart illustrating a band lineup of the conduction band minimums of a stacked body in which the channel layer 115, the spacer layer 121, the intermediate layer 123, and the barrier layer 131 are stacked.

As illustrated in FIGS. 2 and 3, the height of the conduction band minimum of the barrier layer 131 is one factor that determines the carrier density of the two-dimensional electron gas layer (2DEG).

For example, as the Al composition of each layer increases, the polarization of each layer increases. The conduction band minimum thus has a sharper slope. In addition, as the thickness of each layer increases, the height of the conduction band minimum increases. It is thus possible to increase the carrier density of the two-dimensional electron gas layer (2DEG) by appropriately controlling the thickness and the composition of each of the layers from the barrier layer 131 to the channel layer 115 and controlling the height of the conduction band minimum of the barrier layer 131.

For example, it is preferable that the barrier layer 131 include Alₓ₂In₍₁₋ₓ₂₎N having a higher Al composition ratio than that of Alₓ₁In_{y1}Ga_{(1-x1-y1)}N included in the intermediate layer 123. In other words, in a case where the barrier layer 131 includes a nitride semiconductor satisfying x1<x2 as compared with the intermediate layer 123, the barrier layer 131 is able to obtain greater polarization. This makes it possible to further increase the carrier concentration of the two-dimensional electron gas layer (2DEG). For example, in a case where the barrier layer 131 includes a nitride semiconductor having x2 exceeding 0.7, the barrier layer 131 is able to obtain greater polarization. This makes it possible to further increase the carrier concentration of the two-dimensional electron gas layer (2DEG).

In addition, it is preferable that the barrier layer 131 and the intermediate layer 123 each include a nitride semiconductor satisfying x1<x2 and y1<(1−x2). In such a case, it is possible to further increase the polarization of the barrier layer 131 and the barrier layer 131 and the intermediate layer 123 thus allow the two-dimensional electron gas layer (2DEG) to have further higher carrier concentration.

Further, it is preferable that the barrier layer have a thickness of 4 nm or more and 20 nm or less. In such a case, it is possible to appropriately control the profile of the band gap of the semiconductor device 100 and the barrier layer 131 thus makes it possible to further increase the carrier density of the two-dimensional electron gas layer (2DEG) generated in the channel layer 115. It is to be noted that it is more preferable that the barrier layer have a thickness of 8 nm or more and 15 nm or less.

The regrowth layer 141 includes a nitride semiconductor including an n-type impurity. The regrowth layers 141 are provided on both sides of the barrier layer 131, the intermediate layer 123, the spacer layer 121, and the channel layer 115 across the gate electrode 153. Specifically, the regrowth layers 141 are provided by filling a pair of recessed sections with n-type nitride semiconductors. The pair of recessed sections is obtained by digging the regions from the barrier layer 131 to the channel layer 115. For example, the regrowth layers 141 may be provided by selectively growing a nitride semiconductor including an n-type impurity epitaxially in the recessed sections provided in the regions corresponding to the source electrode 143S and the drain electrode 143D by using a selection mask.

Each of the regrowth layers 141 has higher electrical conductivity than that of the barrier layer 131. This makes it possible to electrically couple the source electrode 143S and the drain electrode 143D, and the two-dimensional electron gas layer (2DEG) with low resistance. The source electrode 143S and the drain electrode 143D are provided on the regrowth layers 141. For example, each of the regrowth layers may include GaN including an n-type impurity such as Si or Ge at 1.0×10¹⁹/cm³ or more. Alternatively, each of the regrowth layers 141 may include AlInGaN, which is easier than GaN to grow at a low temperature and includes an n-type impurity.

The source electrode 143S and the drain electrode 143D each include an electrically conductive material. The source electrode 143S and the drain electrode 143D are provided on the regrowth layers 141 provided on both sides of the gate electrode 153. It is possible to electrically couple the source electrode 143S and the drain electrode 143D to the two-dimensional electron gas layer (2DEG) through the regrowth layers 141. The two-dimensional electron gas layer (2DEG) is generated in the channel layer 115. The source electrode 143S and the drain electrode 143D may be each provided to have a structure in which Ti (titanium), Al (aluminum), Ni (nickel), and Au (gold) are sequentially stacked from the regrowth layer 141 side.

The gate insulating film 151 includes an insulative material. The gate insulating film 151 is provided on the barrier layer 131. Specifically, the gate insulating film 151 is provided by using a material having an insulation property with respect to the barrier layer 131 and the gate electrode 153. This allows the gate insulating film 151 to protect the surface of the barrier layer 131 from an impurity such as ions and suppress a decrease in the characteristics of the semiconductor device 100 by offering a favorable surface for the barrier layer 131. For example, the gate insulating film 151 may be provided as a single layer film or a stacked film of Al₂O₃ or HfO₂ that has a film thickness of about 10 nm.

The gate electrode 153 includes an electrically conductive material. The gate electrode 153 is provided on the gate insulating film 151. The gate electrode 153 is provided between the source electrode 143S and the drain electrode 143D. The gate electrode 153 is included in an MIS (Metal-Insulator-Semiconductor) gate along with the gate insulating film 151. For example, the gate electrode 153 may be provided by stacking Ni (nickel) and Au (gold) from the gate insulating film 151 side.

The gate electrode 153 makes it possible to control the carrier concentration of the two-dimensional electron gas layer (2DEG) formed in the channel layer 115 by using an applied voltage. Specifically, the gate electrode 153 makes it possible to control the carrier concentration of the two-dimensional electron gas layer (2DEG) generated in the channel layer 115 with an electric field effect by controlling the thickness of a depletion layer formed in the barrier layer 131 below with an application voltage.

As described above, it is possible in the semiconductor device 100 according to the present embodiment to suppress heat making unclear the interface between the channel layer 115 and the barrier layer 131. This makes it possible to suppress the deterioration of the layer structure of the channel layer 115 and the barrier layer 131 by heat. The technology according to the present disclosure thus makes it possible to increase the heat resistance of the semiconductor device 100.

This allows for crystal growth at a further higher temperature in the semiconductor device 100 according to the present embodiment in forming the regrowth layers 141. It is thus possible to increase the crystallinity of the regrowth layers 141. This allows the semiconductor device 100 to have reduced contact resistance between the source electrode 143S and the drain electrode 143D, and the two-dimensional electron gas layer (2DEG) and have higher power efficiency.

In addition, it is possible in the semiconductor device 100 according to the present embodiment to suppress the deterioration of the sheet resistance of the two-dimensional electron gas layer (2DEG) in forming the regrowth layers 141 and thus increase the power efficiency.

Further, it is possible in the semiconductor device 100 according to the present embodiment to use MOCVD (Metal Organic Chemical Vapor Deposition), which is a high temperature process, to form the regrowth layers 141. This makes it possible to form the regrowth layers 141 more selectively in the semiconductor device 100. It is therefore possible to simplify a process step such as removing the regrowth layers 141 formed in unintended regions. In addition, controlling the gas atmosphere with H₂, N₂, or NH₃ before the regrowth layers 141 are regrown makes it possible to clean the regrowth surfaces in the semiconductor device 100 in the MOCVD. It is thus possible in the semiconductor device 100 to reduce the contact resistance and the carrier trap at the interface of each of the regrown layers 141.

### 2. Method of Manufacturing Semiconductor Device

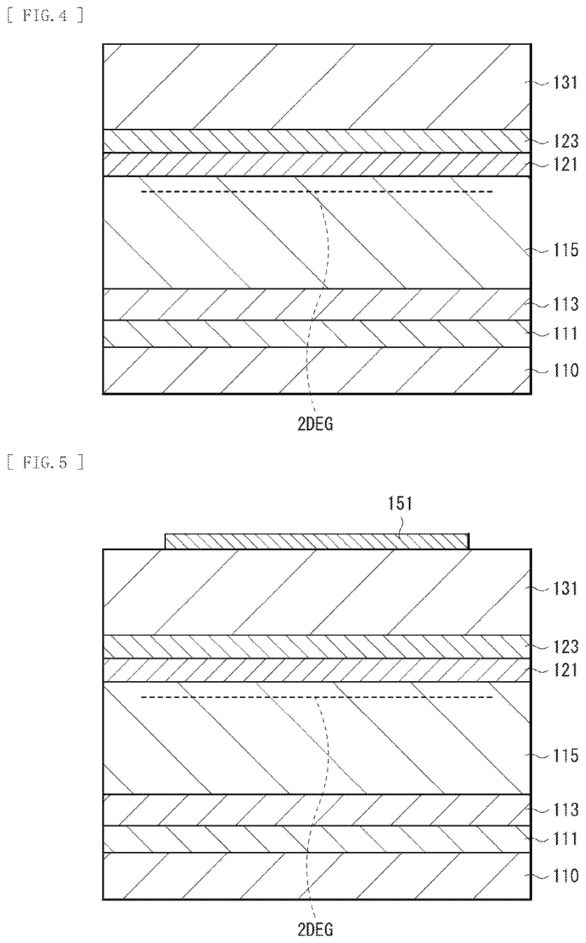

Next, an example of a method of manufacturing the semiconductor device 100 according to the present embodiment is described with reference to FIGS. 4 to 9. FIGS. 4 to 9 are vertical cross-sectional views of the respective steps of the method of manufacturing the semiconductor device 100 according to the present embodiment.

First, as illustrated in FIG. 4, the first buffer layer 111, the second buffer layer 113, the channel layer 115, the spacer layer 121, the intermediate layer 123, and the barrier layer 131 are sequentially grown epitaxially, for example, on the substrate 110. It is to be noted that it is possible to use a Si substrate, a sapphire substrate, a SiC substrate, a GaN substrate, an AlN substrate, a GaAs substrate, a ZnO substrate, a ScAlMgO substrate, or the like for the substrate 110, but the following describes, as an example, a case where a Si substrate is used.

For example, first, a Si substrate having a (111) plane as the principal surface is introduced into a MOCVD device and the Si substrate is subjected to thermal cleaning at 1000° C. for about ten minutes. After that, AlN is epitaxially grown at about 700° C. to 1100° C. to have a thickness of 100 nm to 300 nm. This forms the first buffer layer 111. Next, AlGaN having an Al composition of about 0.20 is epitaxially grown on the first buffer layer 111 at about 900° C. to 1100° C. to have a thickness of 100 nm to 500 nm. This forms the second buffer layer 113. Subsequently, GaN is epitaxially grown on the second buffer layer 113 at about 900° C. to 1100° C. to have a thickness of 500 nm to 2000 nm. This forms the channel layer 115.

After that, AlN is epitaxially grown on the channel layer 115 at 900° C. to 1100° C. to have a thickness of about 0.5 nm to 5 nm. This forms the spacer layer 121. Next, AlInGaN is epitaxially grown on the spacer layer 121 at 700° C. to 900° C. to have a thickness of about 0.5 nm to 5 nm. This forms the intermediate layer 123. Subsequently, AlInN is epitaxially grown on the intermediate layer 123 at 700° C. to 900° C. to have a thickness of about 5 nm to 20 nm. This forms the barrier layer 131.

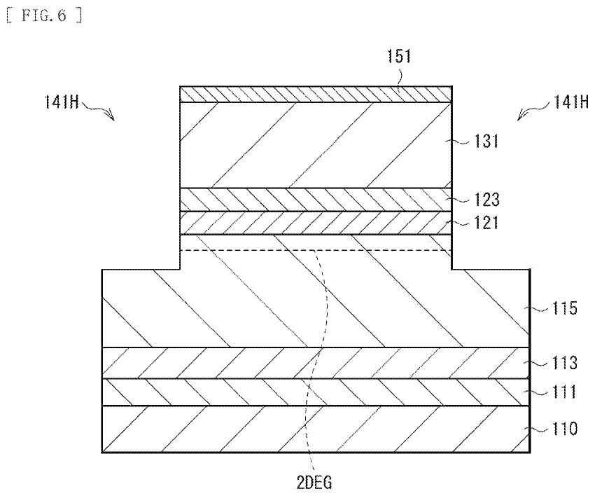

Next, as illustrated in FIG. 5, a film of SiN, SiO₂, Al₂O₃, or the like is formed on the barrier layer 131 to form the gate insulating film 151. Subsequently, the gate insulating film 151 is subjected to wet etching by using a resist to remove the gate insulating film 151 in the regions corresponding to the source electrode 143S and the drain electrode 143D. The resist has been patterned to make openings in the regions corresponding to the source electrode 143S and the drain electrode 143D.

Subsequently, as illustrated in FIG. 6, the barrier layer 131, the intermediate layer 123, the spacer layer 121, and the channel layer 115 in the regions corresponding to the source electrode 143S and the drain electrode 143D are removed by dry etching to form opening sections 141H each having a depth of about 100 nm.

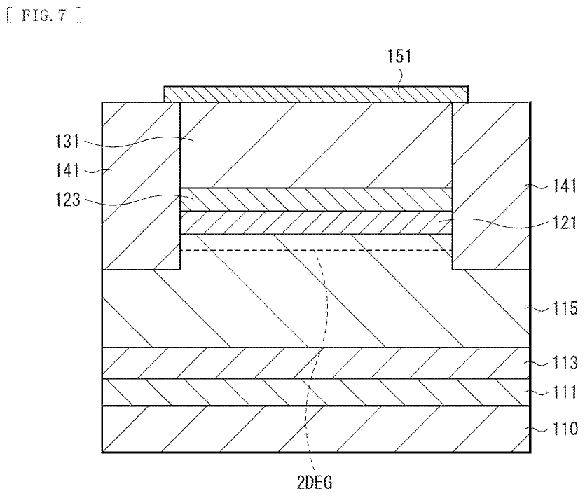

Next, as illustrated in FIG. 7, n-type GaN is selectively grown epitaxially in the opening sections 141H by using MOCVD, MBE (Molecular Beam Epitaxy), or sputtering. This forms the regrowth layers 141. In this case, it is possible to use, for example, Si, Ge, or the like as the n-type impurity.

Subsequently, as illustrated in FIG. 8, Ti, Al, Ni, and Au are sequentially stacked on the regrowth layers 141 to form the source electrode 143S and the drain electrode 143D.

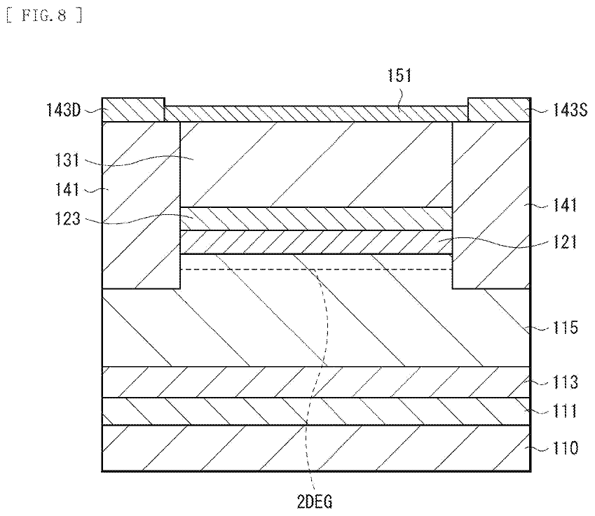

After that, as illustrated in FIG. 9, Ni and Au are sequentially stacked on the gate insulating film 151 between the source electrode 143S and the drain electrode 143D to form the gate electrode 153.

It is possible to form the semiconductor device 100 according to the present embodiment through the steps described above.

### 3. Modification Examples

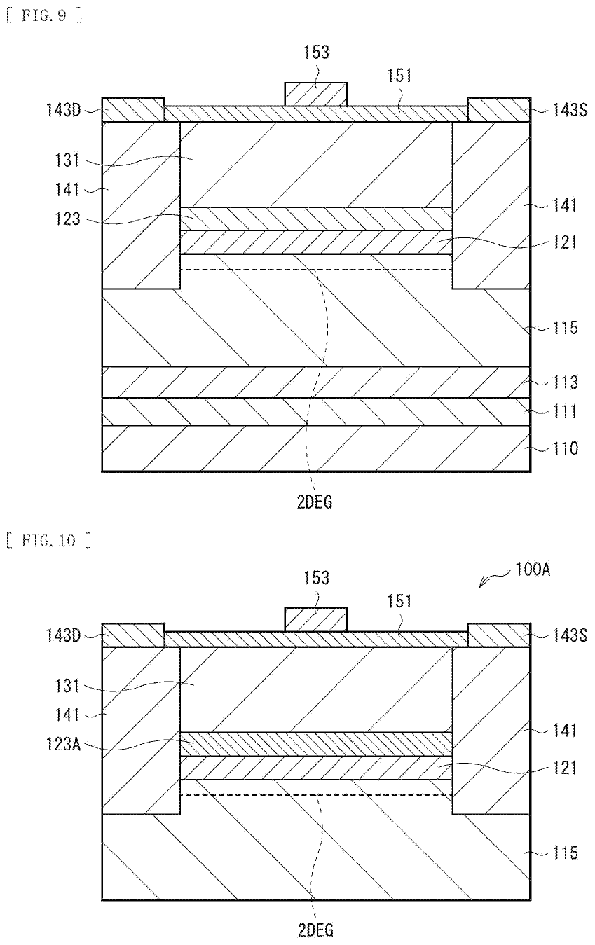

Subsequently, first to fourth modification examples of the semiconductor device 100 according to the present embodiment are described with reference to FIGS. 10 to 13. It is to be noted that FIGS. 10 to 13 each illustrate only the components above the second buffer layer 113. In the semiconductor device according to any of first to fourth modification examples, the second buffer layer 113 and the components below the second buffer layer 113 are substantially similar to those of the semiconductor device 100 illustrated in FIG. 1.

### First Modification Example

FIG. 10 is a vertical cross-sectional view of a configuration of a semiconductor device 100A according to the first modification example. The semiconductor device 100A according to the first modification example is different from the semiconductor device 100 illustrated in FIG. 1 in that the composition of AlInGaN included in an intermediate layer 123A fluctuates in the stack direction of the semiconductor device 100A.

Specifically, the intermediate layer 123A may be provided to decrease the Ga composition ratio (1-x1-y1) of Alₓ₁In_{y1}Ga_{(1-x1-y1)}N(0<x1<1, 0<y1<1, and 0<x1+y1<1) step by step or continuously in the direction from the spacer layer 121 side to the barrier layer 131 side. In other words, the intermediate layer 123A may be provided to have a lower Ga composition ratio in the crystal growth direction. This allows the intermediate layer 123A to reduce the composition difference between the nitride semiconductors included in the spacer layer 121 and the barrier layer 131. This makes it possible to epitaxially grow the respective layers more easily.

### Second Modification Example

FIG. 11 is a vertical cross-sectional view of a configuration of a semiconductor device 100B according to the second modification example. The semiconductor device 100B according to the second modification example is different from the semiconductor device 100 illustrated in FIG. 1 in that there is further provided a graded layer 125 between the intermediate layer 123 and the barrier layer 131.

Specifically, the graded layer 125 is provided between the intermediate layer 123 and the barrier layer 131. The graded layer 125 may include AlInGaN whose Ga composition ratio decreases step by step or continuously in the direction from the intermediate layer 123 side to the barrier layer 131 side. In addition, the graded layer 125 may have, for example, a thickness of 0.5 nm or more and 5 nm or less. This allows the graded layer 125 to reduce the composition difference between the nitride semiconductors included in the intermediate layer 123 and the barrier layer 131. This makes it possible to epitaxially grow the respective layers more easily.

FIG. 11 illustrates the example in which the graded layer 125 is provided between the intermediate layer 123 and the barrier layer 131, but the present modification example is not limited to the example. The graded layer 125 may also be provided between the spacer layer 121 and the intermediate layer 123. Even in such a case, the graded layer 125 is able to reduce the composition difference between the nitride semiconductors included in the spacer layer 121 and the intermediate layer 123. This makes it possible to epitaxially grow the respective layers more easily.

### Third Modification Example

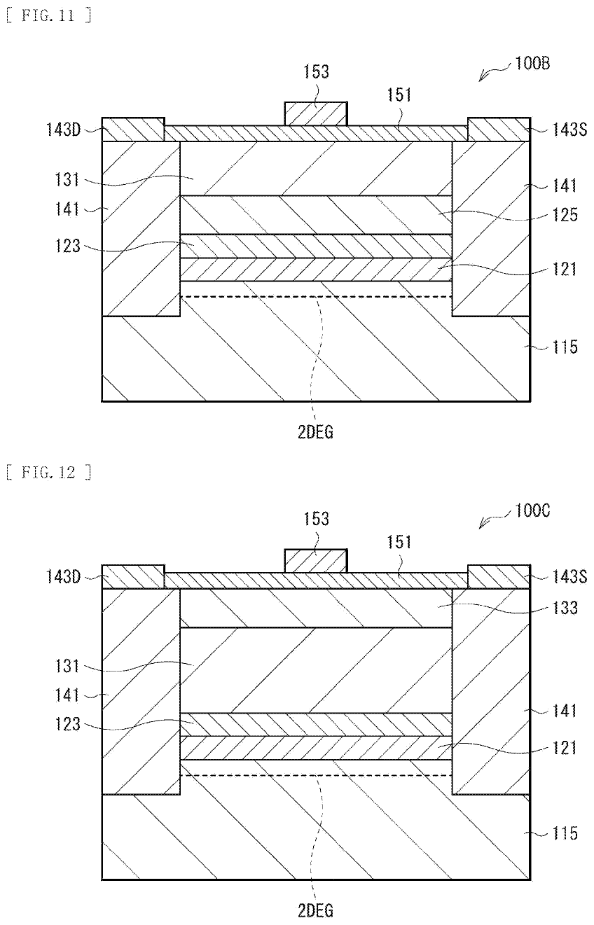

FIG. 12 is a vertical cross-sectional view of a configuration of a semiconductor device 100C according to the third modification example. The semiconductor device 100C according to the third modification example is different from the semiconductor device 100 illustrated in FIG. 1 in that there is provided a protective layer 133 on the barrier layer 131.

Specifically, the protective layer 133 includes AlInGaN. The protective layer 133 is provided on the barrier layer 131. In addition, the protective layer 133 may have, for example, a thickness of 0.5 nm or more and 5 nm or less. This allows the protective layer 133 to protect the barrier layer 131 from a film formation process or the like of the gate insulating film 151. It is thus possible to suppress the deterioration of the crystallinity of the barrier layer 131 after the formation of the barrier layer 131.

### Fourth Modification Example

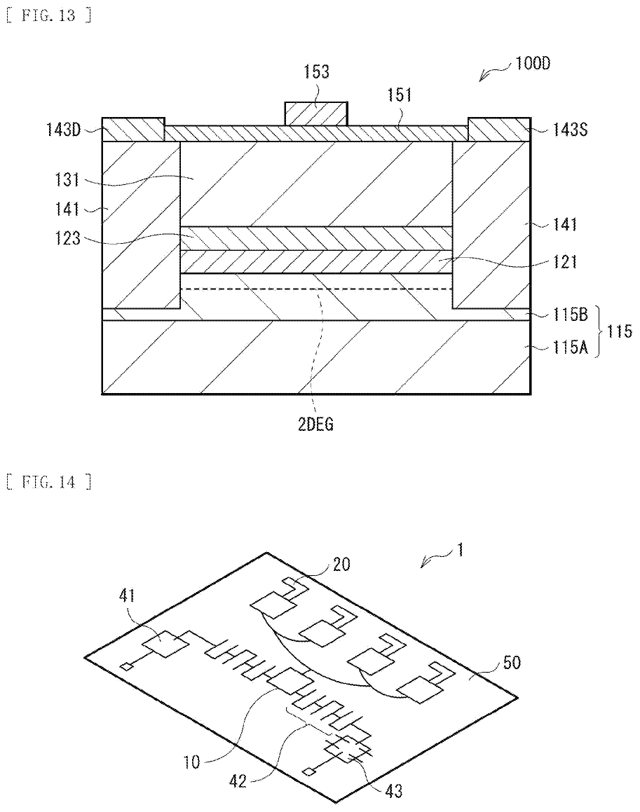

FIG. 13 is a vertical cross-sectional view of a configuration of a semiconductor device 100D according to the fourth modification example. The semiconductor device 100D according to the fourth modification example is different from the semiconductor device 100 illustrated in FIG. 1 in that the channel layer 115 includes an upper channel layer 115B and a lower channel layer 115A.

Specifically, the lower channel layer 115A may include, for example, GaN. The upper channel layer 115B may include, for example, AlGaN, InGaN, or AlInGaN.

The two-dimensional electron gas layer (2DEG) is generated in the upper channel layer 115B by using the difference from the magnitude of the polarization of the spacer layer 121, the magnitude of the polarization of the intermediate layer 123, and the magnitude of the polarization of the barrier layer 131 provided on the upper channel layer 115B. The upper channel layer 115B thus includes a nitride semiconductor having a smaller band gap than the band gaps of the spacer layer 121, the intermediate layer 123, and the barrier layer 131. In contrast, the lower channel layer 115A is not contributed to the generation of the two-dimensional electron gas layer (2DEG). The lower channel layer 115A thus includes a nitride semiconductor, taking into consideration the easiness of epitaxial growth or the like instead of the size of the band gap.

Even in a case where the channel layer 115 includes a plurality of layers, the semiconductor device 100D is able to achieve an effect similar to that of the semiconductor device 100 illustrated in FIG. 1.

It is to be noted that it is also possible to combine the modification examples described above with each other.

### 4. Application Examples

### (4.1. Semiconductor Module)

Subsequently, a semiconductor module that is a first application example of the technology according to the present disclosure is described with reference to FIG. 14. FIG. 14 is a schematic perspective view of a configuration of a semiconductor module 1.

As illustrated in FIG. 14, the semiconductor module 1 is an antenna-integrated module in which, for example, a plurality of array-shaped edge antennas 20 and front-end components are implemented on one chip 50 as a module. The front-end components include a switch 10, a low-noise amplifier 41, a bandpass filter 42, a power amplifier 43, and the like. The semiconductor module 1 may be used, for example, as a transceiver for wireless communication.

The semiconductor module 1 includes, for example, the semiconductor device 100 according to the present embodiment as a transistor included in the switch 10, the low-noise amplifier 41, the power amplifier 43, or the like. For example, the fifth-generation mobile communication (5G), which uses radio waves in a higher frequency band, has a greater propagation loss of radio waves. The semiconductor module 1 supporting 5G is thus requested to transmit radio waves with higher power. The semiconductor module 1 including the semiconductor device 100 according to the present embodiment is allowed to have higher device characteristics. It is therefore possible to perform wireless communication with high power, low power consumption, and high reliability. In other words, it is possible to use the semiconductor module 1 more favorably for the fifth-generation mobile communication (5G).

### (4.2. Wireless Communication Apparatus)

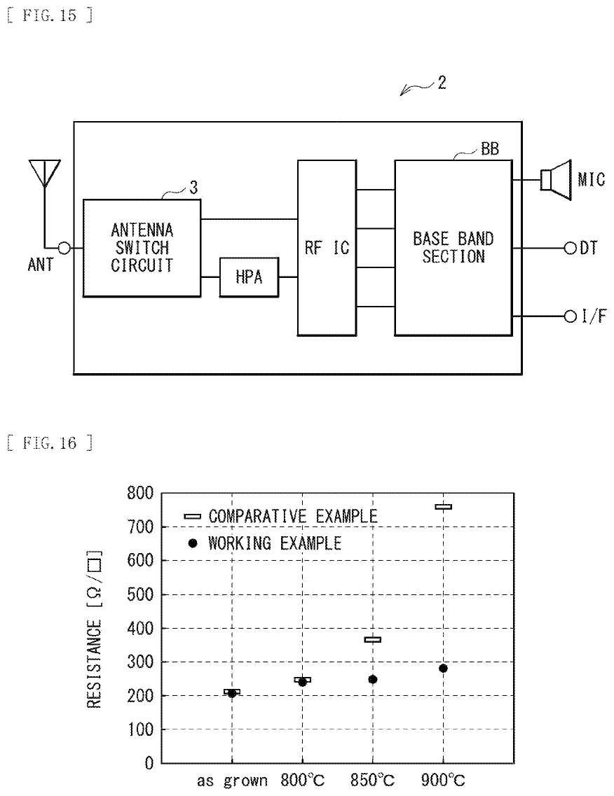

Next, a wireless communication apparatus that is a second application example of the technology according to the present disclosure is described with reference to FIG. 15. FIG. 15 is a block diagram illustrating a configuration of a wireless communication apparatus 2.

As illustrated in FIG. 15, the wireless communication apparatus 2 includes an antenna ANT, an antenna switch circuit 3, a high-power amplifier HPA, a radio frequency integrated circuit RFIC(Radio Frequency Integrated Circuit), a base band section BB, a sound output section MIC, a data output section DT, and an interface section I/F (e.g., wireless LAN (Wireless Local Area Network: W-LAN), Bluetooth (registered trademark), or the like). The wireless communication apparatus 2 is, for example, a mobile phone system having multiple functions including voice, data communication, LAN connection, and the like.

Upon transmission, the base band section BB in the wireless communication apparatus 2 outputs a transmission signal to the antenna ANT through the radio frequency integrated circuit RFIC, the high-power amplifier HPA, and the antenna switch circuit 3. In addition, upon reception, the antenna ANT in the wireless communication apparatus 2 inputs a reception signal to the base band section BB through the antenna switch circuit 3 and the radio frequency integrated circuit RFIC. The reception signal processed by the base band section BB is outputted, for example, from the sound output section MIC, the data output section DT, or the interface section I/F to the outside of the wireless communication apparatus 2.

The wireless communication apparatus 2 includes the semiconductor device 100 according to the present embodiment as a transistor included in the antenna switch circuit 3, the high-power amplifier HPA, the radio frequency integrated circuit RFIC, the base band section BB, or the like. This allows the wireless communication apparatus 2 to have higher device characteristics. It is therefore possible to perform wireless communication with high power, low power consumption, and high reliability.

### Working Example

The following describes, in detail, the practicability and the effects of the technology according to the present disclosure by using a stacked body in which the channel layer to the barrier layer are stacked. The technology according to the present disclosure is not, however, limited to the following example.

### Working Example

A spacer layer, an intermediate layer, and a barrier layer were sequentially stacked on a channel layer including GaN to fabricate a stacked body according to a working example. The spacer layer included Al_{0.9}Ga_{0.1}N having a film thickness of 1 nm. The intermediate layer included Al_{0.8}In_{0.1}Ga_{0.1}N having a film thickness of 1 nm. The barrier layer included Al_{0.81}In_{0.19}N having a film thickness of 9 nm.

### Comparative Example

A spacer layer, an intermediate layer, and a barrier layer were sequentially stacked on a channel layer including GaN to fabricate a stacked body according to a comparative example. The spacer layer included Al_{0.9}Ga_{0.1}N having a film thickness of 1 nm. The barrier layer included Al_{0.81}In_{0.19}N having a film thickness of 9 nm.

### (Results of Measurement)

The sheet resistance of the two-dimensional electron gas layers generated in the channel layers of the stacked bodies according to the working example and the comparative example was measured in an eddy current method. The sheet resistance of the two-dimensional electron gas layers was measured four times: immediately after the formation of the stacked bodies; after heat treatment at 800° C. for three minutes; after heat treatment at 850° C. for three minutes; or after heat treatment at 900° C. for three minutes. Results of the measurement are illustrated in the scatter diagram of FIG. 16.

In FIG. 16, “as grown” represents results of measurement immediately after the formation of the stacked bodies, “800° C.” represents results of measurement after heat treatment at 800° C. for three minutes, “850° C.” represents results of measurement after heat treatment at 850° C. for three minutes, and “900° C.” represents results of measurement after heat treatment at 900° C. for three minutes.

As illustrated in the scatter diagram of FIG. 16, it is possible in the stacked body according to the working example to suppress an increase in the sheet resistance of the two-dimensional electron gas layer brought about by heat treatment at 850° C. or more as compared with the stacked body according to the comparative example. Specifically, heat treatment at 850° C. for three minutes increases the sheet resistance about 1.5 times and heat treatment at 900° C. for three minutes increases the sheet resistance about four times in the stacked body according to the comparative example. Meanwhile, even heat treatment at 900° C. for three minutes increases the sheet resistance merely about 1.2 times in the stacked body according to the working example. This indicates that the heat resistance of the stacked body according to the working example increases as compared with that of the stacked body according to the comparative example. For example, it is possible in the stacked body according to the working example to suppress the sheet resistance of the two-dimensional electron gas layer at 280Ω/□ or less even after heat treatment at 850° C. for three minutes.

This makes it possible to perform heat treatment at 850° C. for three minutes in the semiconductor device according to the present embodiment by using the stacked body according to the working example. It is thus possible to increase the crystallinity of the regrowth layers. It is thus possible in the semiconductor device according to the present embodiment to suppress the sheet resistance of the two-dimensional electron gas layer at 280Q/0 or less and reduce the contact resistance between the source electrode and the drain electrode, and the two-dimensional electron gas layer. This makes it possible to increase the power efficiency.

The technology according to the present disclosure has been described above with reference to the embodiment and the modification examples. However, the technology according to the present disclosure is not limited to the embodiment or the like described above. A variety of modifications are possible.

Further, not all of the components and operations described in the respective embodiments are necessary as the components and operations according to the present disclosure. For example, among the elements in the respective embodiments, elements not recited in an independent claim based on the most generic concept of the present disclosure are to be understood as optional components.

The terms used throughout this specification and the appended claims should be construed as “non-limiting” terms. For example, the term “including” or “included” should be construed as “not limited to what is described as being included”. The term “having” should be construed as “not limited to what is described as having”.

The terms used in this specification are used merely for the convenience of description and include terms that are not used to limit the configuration and the operation. For example, the terms such as “right”, “left”, “up”, and “down” only indicate directions in the diagrams being referred to. In addition, the terms “inside” and “outside” only indicate a direction toward the center of a component of interest and a direction away from the center of a component of interest, respectively. The same applies to terms similar to these and terms with the similar purpose.

It is to be noted that the technology according to the present disclosure may have configurations as follows. The technology according to the present disclosure having the following configurations makes it possible in the semiconductor device according to the present embodiment to suppress the diffusion of alloy between the channel layer and the barrier layer by heat treatment. It is therefore possible to suppress an increase in the sheet resistance of the two-dimensional electron gas layer even in a case where heat treatment is performed at a higher temperature. The semiconductor device according to the present embodiment is thus allowed to have higher heat resistance. Effects attained by the technology according to the present disclosure are not necessarily limited to the effects described herein, but may include any of the effects described in the present disclosure.

(1)

A semiconductor device including:

a channel layer including a first nitride semiconductor;

a spacer layer including a second nitride semiconductor having a larger band gap than a band gap of the first nitride semiconductor, the spacer layer being provided on the channel layer;

an intermediate layer including Alₓ₁In_{y1}Ga_{(1-x1-y1)}N(0<x1<1, 0<y1<1, and 0<x1+y1<1), the intermediate layer being provided on the spacer layer; and a barrier layer including Alₓ₂In₍₁₋ₓ₂₎N(0<x2<1), the barrier layer being provided on the intermediate layer.

(2)

The semiconductor device according to (1), in which x1, x2, and y1 satisfy relational expressions of x1<x2 and y1<(1-x2).

(3)

The semiconductor device according to (1) or (2), in which x2 exceeds 0.7.

(4)

The semiconductor device according to any one of (1) to (3), in which the intermediate layer has a thickness of 0.5 nm or more and 10 nm or less.

(5)

The semiconductor device according to any one of (1) to (4), in which the barrier layer has a thickness of 4 nm or more and 20 nm or less.

(6)

The semiconductor device according to any one of (1) to (5), in which a ratio of Ga of Alₓ₁In_{y1}Ga_{(1-x1-y1)}N included in the intermediate layer decreases from the spacer layer to the barrier layer.

(7)

The semiconductor device according to any one of (1) to (6), in which the second nitride semiconductor includes Alₓ₃In_{y3}Ga_{(1-x3-y3)}N(0<x3<1, 0<y3<1, and 0<x3+y3<1).

(8)

The semiconductor device according to any one of (1) to (7), in which the spacer layer has a thickness of 0.5 nm or more and 3 nm or less.

(9)

The semiconductor device according to any one of (1) to (8), in which the first nitride semiconductor includes Alₓ₄In_{y4}Ga_{(1-x4-y4)}N(0<x4<1, 0<y4<1, and 0<x4+y4<1).

(10)

The semiconductor device according to any one of (1) to (9), further including:

regrowth layers each including n-type AlInGaN, the regrowth layers being provided in a pair of respective recessed sections obtained by digging regions from the barrier layer to the spacer layer;

a source electrode that is provided on one of the regrowth layers; and

a drain electrode that is provided on another of the regrowth layers.

(11)

The semiconductor device according to any one of (1) to (10), further including a gate electrode that is provided above the barrier layer with a gate insulating film interposed in between.

(12)

The semiconductor device according to any one of (1) to (11), in which

a two-dimensional electron gas layer is generated in the channel layer, and

the two-dimensional electron gas layer has a sheet resistance of 280 Ω/□ or less.

(13)

A semiconductor module including

a semiconductor device including
a channel layer including a first nitride semiconductor,
a spacer layer including a second nitride semiconductor having a larger band gap than a band gap of the first nitride semiconductor, the spacer layer being provided on the channel layer,
an intermediate layer including Alₓ₁In_{y1}Ga_{(1-x1-y1)}N(0<x1<1, 0<y1<1, and 0<x1+y1<1), the intermediate layer being provided on the spacer layer, and
a barrier layer including Alₓ₂In₍₁₋ₓ₂₎N(0<x2<1), the barrier layer being provided on the intermediate layer.
   (14)

A wireless communication apparatus including

a semiconductor device including
a channel layer including a first nitride semiconductor,
a spacer layer including a second nitride semiconductor having a larger band gap than a band gap of the first nitride semiconductor, the spacer layer being provided on the channel layer,
an intermediate layer including Alₓ₁In_{y1}Ga_{(1-x1-y1)}N(0<x1<1, 0<y1<1, and 0<x1+y1<1), the intermediate layer being provided on the spacer layer, and
a barrier layer including Alₓ₂In₍₁₋ₓ₂₎N(0<x2<1), the barrier layer being provided on the intermediate layer.

This application claims the priority on the basis of Japanese Patent Application No. 2020-147166 filed with Japan Patent Office on Sep. 1, 2020, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. A semiconductor device comprising:
a channel layer including a first nitride semiconductor;
a spacer layer including a second nitride semiconductor having a larger band gap than a band gap of the first nitride semiconductor, the spacer layer being provided on the channel layer;
an intermediate layer including Alₓ₁In_{y1}Ga_{(1-x1-y1)}N(0<x1<1, 0<y1<1, and 0<x1+y1<1), the intermediate layer being provided on the spacer layer; and
a barrier layer including Alₓ₂In₍₁₋ₓ₂₎N(0<x2<1), the barrier layer being provided on the intermediate layer.

2. The semiconductor device according to claim 1, wherein x1, x2, and y1 satisfy relational expressions of x1<x2 and y1<(1-x2).

3. The semiconductor device according to claim 1, wherein x2 exceeds 0.7.

4. The semiconductor device according to claim 1, wherein the intermediate layer has a thickness of 0.5 nm or more and 10 nm or less.

5. The semiconductor device according to claim 1, wherein the barrier layer has a thickness of 4 nm or more and 20 nm or less.

6. The semiconductor device according to claim 1, wherein a ratio of Ga of Alₓ₁In_{y1}Ga_{(1-x1-y1)}N included in the intermediate layer decreases from the spacer layer to the barrier layer.

7. The semiconductor device according to claim 1, wherein the second nitride semiconductor includes Alₓ₃In_{y3}Ga_{(1-x3-y3)}N(0<x3<1, 0<y3<1, and 0<x3+y3<1).

8. The semiconductor device according to claim 1, wherein the spacer layer has a thickness of 0.5 nm or more and 3 nm or less.

9. The semiconductor device according to claim 1, wherein the first nitride semiconductor includes Alₓ₄In_{y4}Ga_{(1-x4-y4)}N(0<x4<1, 0<y4<1, and 0<x4+y4<1).

10. The semiconductor device according to claim 1, further comprising:
regrowth layers each including n-type AlInGaN, the regrowth layers being provided in a pair of respective recessed sections obtained by digging regions from the barrier layer to the spacer layer;
a source electrode that is provided on one of the regrowth layers; and
a drain electrode that is provided on another of the regrowth layers.

11. The semiconductor device according to claim 1, further comprising a gate electrode that is provided above the barrier layer with a gate insulating film interposed in between.

12. The semiconductor device according to claim 1, wherein
a two-dimensional electron gas layer is generated in the channel layer, and
the two-dimensional electron gas layer has a sheet resistance of 280 Ω/□ or less.

13. A semiconductor module comprising
a semiconductor device including
a channel layer including a first nitride semiconductor,
a spacer layer including a second nitride semiconductor having a larger band gap than a band gap of the first nitride semiconductor, the spacer layer being provided on the channel layer,
an intermediate layer including Alₓ₁In_{y1}Ga_{(1-x1-y1)}N(0<x1<1, 0<y1<1, and 0<x1+y1<1), the intermediate layer being provided on the spacer layer, and
a barrier layer including Alₓ₂In₍₁₋ₓ₂₎N(0<x2<1), the barrier layer being provided on the intermediate layer.

14. A wireless communication apparatus comprising
a semiconductor device including
a channel layer including a first nitride semiconductor,
a spacer layer including a second nitride semiconductor having a larger band gap than a band gap of the first nitride semiconductor, the spacer layer being provided on the channel layer,
an intermediate layer including Alₓ₁In_{y1}Ga_{(1-x1-y1)}N(0<x1<1, 0<y1<1, and 0<x1+y1<1), the intermediate layer being provided on the spacer layer, and
a barrier layer including Alₓ₂In₍₁₋ₓ₂₎N(0<x2<1), the barrier layer being provided on the intermediate layer.
